(19) United States
(12) Patent Application Publication
(10) Pub. No.: US 2025/0224662 A1
(43) Pub. Date: Jul. 10, 2025

(54) PELLICLE FOR EUV LITHOGRAPHY

(71) Applicant: ASML NETHERLANDS B.V., Veldhoven (NL)

(72) Inventors: Paul Alexander VERMEULEN, Eindhoven (NL); Volker Dirk HILDENBRAND, Eindhoven (NL); Inci DONMEZ NOYAN, Eindhoven (NL)

(73) Assignee: ASML NETHERLANDS B.V., Veldhoven (NL)

(21) Appl. No.: 18/844,707

(22) PCT Filed: Feb. 28, 2023
(86) PCT No.: PCT/EP2023/055032

§ 371 Date: Sep. 6, 2024

(30) Foreign Application Priority Data
Apr. 5, 2022 (EP) 22166734.8

(51) Int. Cl. G03F 1/22; G03F 7/00

(52) U.S. Cl. CPC G03F 1/22; G03F 7/70033; G03F 7/70891; G03F 7/7095; G03F 7/70983; G03F 7/70991

(57) ABSTRACT

A pellicle for EUV lithography includes a core layer having silicon and having at least one non-oxidised surface, and a cap layer at at least one major surface of the core layer. The cap layer includes carbon and/or boron. The cap layer may be removed before or during an exposure operation.

### CROSS-REFERENCE TO RELATED APPLICATIONS

This application claims priority of EP Application Serial No. 22166734.8 which was filed on Apr. 5, 2022 and which is incorporated herein in its entirety by reference.

### FIELD

The present invention relates to a pellicle, a lithographic apparatus, a method for making a pellicle, a method for performing EUV lithography and a method for loading a pellicle.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$C D = {k}_{1} * \frac{λ}{N A} \qquad ( 1 )$$

where λ is the wavelength of the radiation used, NA is the numerical aperture of the projection system used to print the pattern, k1 is a process-dependent adjustment factor, also called the Rayleigh constant, and CD is the feature size (or critical dimension) of the printed feature. It follows from equation (1) that reduction of the minimum printable size of features can be obtained in three ways: by shortening the exposure wavelength λ, by increasing the numerical aperture NA or by decreasing the value of k1.

In order to shorten the exposure wavelength and, thus, reduce the minimum printable size, it has been proposed to use an extreme ultraviolet (EUV) radiation source. EUV radiation is electromagnetic radiation having a wavelength within the range of 10-20 nm, for example within the range of 13-14 nm. It has further been proposed that EUV radiation with a wavelength of less than 10 nm could be used, for example within the range of 5-10 nm such as 6.7 nm or 6.8 nm. Such radiation is termed extreme ultraviolet radiation or soft x-ray radiation. Possible sources include, for example, laser-produced plasma sources, discharge plasma sources, or sources based on synchrotron radiation provided by an electron storage ring.

A lithographic apparatus includes a patterning device (e.g., a mask or a reticle). Radiation is provided through or reflected off the patterning device to form an image on a substrate. A pellicle may be provided to protect the patterning device from airborne particles and other forms of contamination. The pellicle for protecting the patterning device may be called a pellicle. Contamination on the surface of the patterning device can cause manufacturing defects on the substrate. The pellicle may comprise a frame and a membrane stretched across the frame.

During use of the pellicle, some material can undesirable outgas from the pellicle. This can cause problems such as undesirably shortening the lifetime of the reticle and/or reducing imaging quality.

It is desirable to provide a pellicle that is more stable and/or has a lower outgassing rate.

### SUMMARY OF THE INVENTION

According to an aspect of the invention, there is provided a pellicle for EUV lithography, the pellicle comprising: a core layer comprising silicon and having at least one non-oxidised surface; and a cap layer at at least one major surface of the core layer; wherein the cap layer comprises carbon and/or boron.

According to an aspect of the invention, there is provided an EUV lithographic apparatus comprising: a low pressure environment for an EUV radiation beam path for an exposure operation; and a pellicle located in the low pressure environment, the pellicle comprising a core layer comprising a compound comprising molybdenum embedded in a matrix comprising silicon, wherein the core layer has at least one non-oxidised surface and is exposed to a hydrogen plasma in the low pressure environment.

According to an aspect of the invention, there is provided an EUV lithographic apparatus comprising: a low pressure environment for an EUV radiation beam path for an exposure operation; and a loading bay for holding a pellicle to be introduced into the low pressure environment, the pellicle comprising a core layer comprising silicon and at least one cap layer comprising carbon and/or boron covering the core layer; wherein the loading bay comprises an etcher configured to etch away the cap layer of a pellicle so as to expose the core layer.

According to an aspect of the invention, there is provided an EUV lithographic apparatus comprising: a low pressure environment for an EUV radiation beam path for an exposure operation; and a pellicle located in the low pressure environment, the pellicle comprising a core layer comprising silicon and a cap layer comprising carbon and/or boron at at least one major surface of the core layer; and a pellicle heater configured to maintain the pellicle at a temperature of at least 500° C.

According to an aspect of the invention, there is provided a method for making a pellicle for EUV lithography, the method comprising: depositing a core layer comprising silicon and having at least one non-oxidised surface; and depositing a cap layer at at least one major surface of the core layer, wherein the cap layer comprises carbon and/or boron.

According to an aspect of the invention, there is provided a method for performing EUV lithography, the method comprising: projecting an EUV radiation beam through a low pressure environment onto a substrate in an exposure operation; wherein the EUV radiation beam passes through a pellicle located in the low pressure environment, the pellicle comprising a core layer comprising a compound comprising molybdenum embedded in a matrix comprising silicon, wherein the core layer has at least one non-oxidised surface and is exposed to a hydrogen plasma in the low pressure environment.

According to an aspect of the invention, there is provided a method for loading a pellicle into a low pressure environment of an EUV lithographic apparatus, the method comprising: holding in a loading bay a pellicle to be introduced into the low pressure environment, the pellicle comprising a core layer comprising silicon and at least one cap layer comprising carbon and/or boron covering the core layer; etching away the cap layer of a pellicle so as to expose the core layer; and moving the pellicle from the loading bay into the low pressure environment for an exposure operation.

According to an aspect of the invention, there is provided a method for performing EUV lithography, the method comprising: projecting an EUV radiation beam through a low pressure environment onto a substrate in an exposure operation, wherein the EUV radiation beam passes through a pellicle located in the low pressure environment, the pellicle comprising a core layer comprising silicon and a cap layer comprising carbon and/or boron at at least one major surface of the core layer; and maintaining the pellicle at a temperature of at least 500° C.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 is a more detailed view of the lithographic apparatus;

FIG. 3 schematically depicts, in cross-section, part of a pellicle according to an embodiment of the invention;

FIG. 4 schematically depicts a pellicle according to an embodiment of the invention;

FIG. 5 schematically depicts a pellicle according to an embodiment of the invention;

FIG. 6 schematically depicts a lithographic apparatus according to an embodiment of the invention; and

FIG. 7 schematically depicts a lithographic apparatus according to an embodiment of the invention.

### DETAILED DESCRIPTION

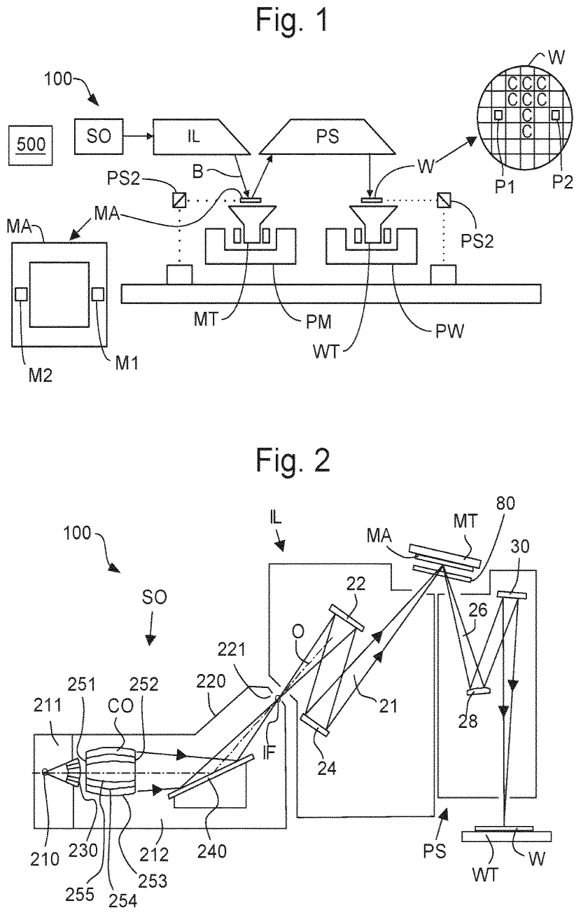

FIG. 1 schematically depicts a lithographic apparatus 100 including a source collector module SO according to one embodiment of the invention. The apparatus 100 comprises:
an illumination system (or illuminator) IL configured to condition a radiation beam B (e.g., EUV radiation).
a support structure (e.g., a mask table) MT constructed to support a patterning device (e.g., a mask or a reticle) MA and connected to a first positioner PM configured to accurately position the patterning device;
a substrate table (e.g., a wafer table) WT constructed to hold a substrate (e.g., a resist-coated wafer) W and connected to a second positioner PW configured to accurately position the substrate; and
a projection system (e.g., a reflective projection system) PS configured to project a pattern imparted to the radiation beam B by patterning device MA onto a target portion C (e.g., comprising one or more dies) of the substrate W.

The illumination system IL may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure MT can use mechanical, vacuum, electrostatic or other clamping techniques to hold the patterning device MA. The support structure MT may be a frame or a table, for example, which may be fixed or movable as required. The support structure MT may ensure that the patterning device MA is at a desired position, for example with respect to the projection system PS.

The term “patterning device” should be broadly interpreted as referring to any device that can be used to impart a radiation beam B with a pattern in its cross-section such as to create a pattern in a target portion C of the substrate W. The pattern imparted to the radiation beam B may correspond to a particular functional layer in a device being created in the target portion C, such as an integrated circuit.

The patterning device MA may be transmissive or reflective. Examples of patterning devices include masks, programmable mirror arrays, and programmable liquid-crystal display (LCD) panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

The projection system PS, like the illumination system IL, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment May therefore be provided to the whole beam path with the aid of a vacuum wall and vacuum pumps.

As here depicted, the lithographic apparatus 100 is of a reflective type (e.g., employing a reflective mask).

The lithographic apparatus 100 may be of a type having two (dual stage) or more substrate tables WT (and/or two or more support structures MT). In such a “multiple stage” lithographic apparatus the additional substrate tables WT (and/or the additional support structures MT) may be used in parallel, or preparatory steps may be carried out on one or more substrate tables WT (and/or one or more support structures MT) while one or more other substrate tables WT (and/or one or more other support structures MT) are being used for exposure.

Referring to FIG. 1, the illumination system IL receives an extreme ultraviolet radiation beam from the source collector module SO. Methods to produce EUV light include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The source collector module SO may be part of an EUV radiation system including a laser, not shown in FIG. 1, for providing the laser beam exciting the fuel. The resulting plasma emits output radiation, e.g., EUV radiation, which is collected using a radiation collector, disposed in the source collector module. The laser and the source collector module SO may be separate entities, for example when a CO₂ laser is used to provide the laser beam for fuel excitation.

In such cases, the laser is not considered to form part of the lithographic apparatus 100 and the radiation beam B is passed from the laser to the source collector module SO with the aid of a beam delivery system comprising, for example, suitable directing mirrors and/or a beam expander. In other cases the source may be an integral part of the source collector module SO, for example when the source is a discharge produced plasma EUV generator, often termed as a DPP source.

The illumination system IL may comprise an adjuster for adjusting the angular intensity distribution of the radiation beam. Generally, at least the outer and/or inner radial extent (commonly referred to as □-outer and □-inner, respectively) of the intensity distribution in a pupil plane of the illumination system IL can be adjusted. In addition, the illumination system IL may comprise various other components, such as facetted field and pupil mirror devices. The illumination system IL may be used to condition the radiation beam B, to have a desired uniformity and intensity distribution in its cross-section.

The radiation beam B is incident on the patterning device (e.g., mask) MA, which is held on the support structure (e.g., mask table) MT, and is patterned by the patterning device MA. After being reflected from the patterning device (e.g., mask) MA, the radiation beam B passes through the projection system PS, which focuses the radiation beam B onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. The patterning device (e.g., mask) MA and the substrate W may be aligned using mask alignment marks M1, M2 and substrate alignment marks P1, P2.

A controller 500 controls the overall operations of the lithographic apparatus 100 and in particular performs an operation process described further below. Controller 500 can be embodied as a suitably-programmed general purpose computer comprising a central processing unit, volatile and non-volatile storage means, one or more input and output devices such as a keyboard and screen, one or more network connections and one or more interfaces to the various parts of the lithographic apparatus 100. It will be appreciated that a one-to-one relationship between controlling computer and lithographic apparatus 100 is not necessary. In an embodiment of the invention one computer can control multiple lithographic apparatuses 100. In an embodiment of the invention, multiple networked computers can be used to control one lithographic apparatus 100. The controller 500 may also be configured to control one or more associated process devices and substrate handling devices in a lithocell or cluster of which the lithographic apparatus 100 forms a part. The controller 500 can also be configured to be subordinate to a supervisory control system of a lithocell or cluster and/or an overall control system of a fab.

FIG. 2 shows the lithographic apparatus 100 in more detail, including the source collector module SO, the illumination system IL, and the projection system PS. An EUV radiation emitting plasma 210 may be formed by a plasma source. EUV radiation may be produced by a gas or vapor, for example Xe gas, Li vapor or Sn vapor in which the radiation emitting plasma 210 is created to emit radiation in the EUV range of the electromagnetic spectrum. In an embodiment, a plasma of excited tin (Sn) is provided to produce EUV radiation.

The radiation emitted by the radiation emitting plasma 210 is passed from a source chamber 211 into a collector chamber 212.

The collector chamber 212 may include a radiation collector CO. Radiation that traverses the radiation collector CO can be focused in a virtual source point IF. The virtual source point IF is commonly referred to as the intermediate focus, and the source collector module SO is arranged such that the virtual source point IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the unpatterned beam 21, at the patterning device MA, as well as a desired uniformity of radiation intensity at the patterning device MA. Upon reflection of the unpatterned beam 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in the illumination system IL and the projection system PS. Further, there may be more mirrors present than those shown in the Figures, for example there may be 1-6 additional reflective elements present in the projection system PS than shown in FIG. 2.

Alternatively, the source collector module SO may be part of an LPP radiation system.

As depicted in FIG. 1, in an embodiment the lithographic apparatus 100 comprises an illumination system IL and a projection system PS. The illumination system IL is configured to emit a radiation beam B. The projection system PS is separated from the substrate table WT by an intervening space. The projection system PS is configured to project a pattern imparted to the radiation beam B onto the substrate W. The pattern is for EUV radiation of the radiation beam B.

The space intervening between the projection system PS and the substrate table WT can be at least partially evacuated. The intervening space may be delimited at the location of the projection system PS by a solid surface from which the employed radiation is directed toward the substrate table WT.

In an embodiment the lithographic apparatus 100 comprises a dynamic gas lock. The dynamic gas lock comprises a pellicle 80. In an embodiment the dynamic gas lock comprises a hollow part covered by a pellicle 80 located in the intervening space. The hollow part is situated around the path of the radiation. In an embodiment the lithographic apparatus 100 comprises a gas blower configured to flush the inside of the hollow part with a flow of gas. The radiation travels through the pellicle before impinging on the substrate W.

In an embodiment the lithographic apparatus 100 comprises a pellicle 80. As explained above, in an embodiment the pellicle 80 is for a dynamic gas lock. In this case the pellicle 80 functions as a filter for filtering IR radiation and/or DUV radiation. Additionally or alternatively, in an embodiment the pellicle 80 is pellicle for the patterning device MA for EUV lithography. The pellicle 80 of the present invention can be used for a dynamic gas lock or for a pellicle or for another purpose such as a spectral purity filter. In an embodiment the pellicle 80 comprises a membrane 40, which may also be called a membrane stack. In an embodiment the membrane is configured to transmit at least 80% of incident EUV radiation.

In an embodiment the pellicle 80 is configured to seal off the patterning device MA to protect the patterning device MA from airborne particles and other forms of contamination. Contamination on the surface of the patterning device MA can cause manufacturing defects on the substrate W. For example, in an embodiment the pellicle is configured to reduce the likelihood that particles might migrate into a stepping field of the patterning device MA in the lithographic apparatus 100.

If the patterning device MA is left unprotected, the contamination can require the patterning device MA to be cleaned or discarded. Cleaning the patterning device MA interrupts valuable manufacturing time and discarding the patterning device MA is costly. Replacing the patterning device MA also interrupts valuable manufacturing time.

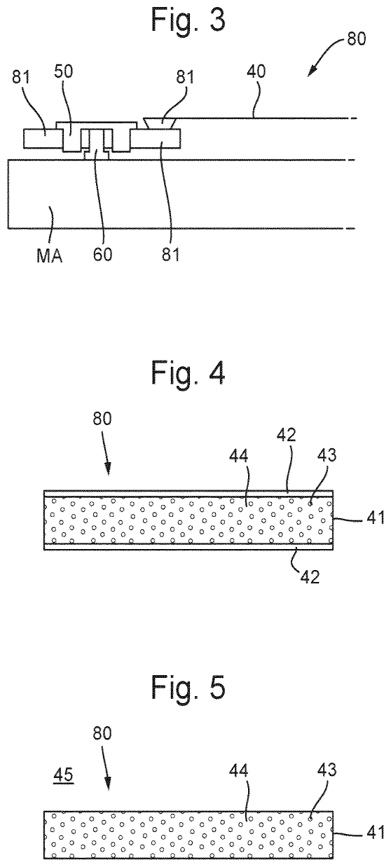

FIG. 3 schematically depicts, in cross-section, part of a pellicle 80 according to an embodiment of the invention. The pellicle 80 is for EUV lithography. The pellicle 80 comprises a membrane 40. The membrane 40 is transmissive for EUV radiation. Of course the membrane 40 may not transmit 100% of incident EUV radiation. As shown in FIG. 3, in an embodiment the membrane 40 is substantially planar. In an embodiment the plane of the membrane 40 is substantially parallel to the plane of the patterning device MA.

The pellicle 80 has a shape such as a square, a circle or a rectangle, for example. The shape of the pellicle 80 is not particularly limited. The size of the pellicle 80 is not particularly limited. For example, in an embodiment the pellicle 80 has a diameter in the range of from about 100 mm to about 500 mm, for example about 200 mm.

As depicted in FIG. 3, in an embodiment the pellicle 80 comprises a frame 81. The frame 81 is configured to hold the membrane 40. The frame 81 provides mechanical stability to the membrane 40. The frame 81 is configured to reduce the possibility of the membrane 40 being deformed away from its planar shape. In an embodiment, a pre-tension is applied to the membrane 40 during its manufacture. The frame 81 is configured to maintain the tension in the membrane 40 so that the membrane 40 does not have an undulating shape during use of the lithographic apparatus 100. In an embodiment the frame 81 extends along the perimeter of the membrane 40. The outer periphery of the membrane 40 is positioned on top of the frame 81 (according to the view of FIG. 3).

As depicted in FIG. 3, in an embodiment the frame 81 comprises a border portion directly connected to the membrane 40. The border portion of the frame 81 is formed by the second material 74 described later in this disclosure. As shown in FIG. 3, in an embodiment the frame 81 further comprises an extension portion that makes it easier for the pellicle 80 to be fixed relative to the patterning device MA. The border portion and the extension portion of the frame 81 may be adhered to each other.

As depicted in FIG. 3, in an embodiment the pellicle 80 comprises a fixture 50. The fixture 50 is arranged to be removably coupled to studs 60 fixed relative to the pattern device MA. Additional details of the assembly are described in WO 2016079051 A2, in particular in FIG. 11 and FIGS. 28 to 31 and the associated description.

FIG. 4 is a schematic diagram of a pellicle 80 according to an embodiment of the invention. FIG. 4 shows a portion of the membrane 40 of the pellicle 80. The pellicle 80 is for EUV lithography. For example, the pellicle 80 may comprise part of a dynamic gas lock of the lithographic apparatus 100 and/or such a pellicle 80 may be used for combining with the patterning device MA. FIG. 4 shows a cross-section of the membrane 40.

As shown in FIG. 4, in an embodiment the pellicle 80 comprises a core layer 41. The core layer 41 forms the main body of the membrane 40 of the pellicle 80. The core layer 41 is configured to transmit EUV radiation. The core layer 41 is configured to be a barrier to particles. In an embodiment the core layer 41 has at least one non-oxidised surface. In an embodiment both major surfaces of the core layer 41 are non-oxidised. Alternatively, one of the major surfaces is oxidized and the other is non-oxidised. The core layer 41 comprises silicon. In an embodiment the core layer 41 comprises SiN. Additionally or alternatively, the core layer 41 comprises elemental silicon, Si. Elemental silicon may be more transmissive to EUV radiation compared to SiN. An embodiment of the invention is expected to increase the proportion of EUV radiation transmitted through the pellicle 80.

Additionally or alternatively, the core layer 41 may comprise other forms of silicon. For example, in an embodiment a core layer 41 comprises ZrSi₂. In an embodiment the core layer 41 comprises SiC. In an embodiment the core layer 41 comprises ZrSi₂Nₓ. In an embodiment the core layer 41 comprises polysilicon.

As shown in FIG. 4, in an embodiment the pellicle 80 comprises a cap layer 42. The cap layer 42 is at at least one major surface of the core layer 41. The core layer 41 has two major surfaces. The major surfaces are planar. In the arrangement shown in FIG. 4, a cap layer 42 is provided at both of the major surfaces of the core layer 41. In an alternative embodiment a cap layer 42 is provided at only one of the major surfaces of the core layer 41. The cap layer 42 may be in direct contact with the core layer 41. There is substantially no intermediate layer between the cap layer 42 and the core layer 41. The core layer 41 consists of a substantially homogeneous material without being stratified. The cap layer 42 has a different composition from the core layer 41.

The cap layer 42 reduces the possibility of native oxide growth at the surfaces of the core layer 41. The cap layer 42 may reduce the possibility of SiO and/or SiN and/or SiON forming at the surface of the core layer 41. A SiON layer may comprise one or more of SiOₓ, SiN_{y} and SiOₓN_{y}. Such materials forming at the surface of the core layer 41 can undesirably outgas in the lithographic apparatus 100. An embodiment of the invention is expected to reduce outgassing from the pellicle 80 in the lithographic apparatus 100.

A core layer 41 that is exposed to atmosphere may develop on its surfaces a native SiON layer. The layer may have a thickness in the region of about 1.5 nm. In use in the lithographic apparatus 100 the pellicle 80 may be subjected to intense EUV radiation, high temperatures and/or hydrogen plasma. Partly due to these conditions, silicon can be removed from the pellicle 80 and in particular from the native SiON layers at the surfaces of the core layer 41. Silicon redisposition is undesirable in the lithographic apparatus 100. For example, silicon that is outgassed from the pellicle 80 can adhere to features on the patterning device MA causing imaging errors. This can result in the patterning device MA having to be replaced early. Silicon in the lithographic apparatus 100 can also potentially deposit on reflecting surfaces which can disturb the imaging quality and/or reduce throughput by absorbing the EUV radiation used for imaging. The cap layer 42 may reduce the rate of silicon outgassing from the pellicle 80.

In an embodiment the cap layer 42 comprises carbon. Additionally or alternatively, the cap layer 42 comprises boron. It is possible that carbon and/or boron may be removed from the pellicle 80 in the lithographic apparatus 100. Carbon and boron may be more readily cleaned in the environment of the lithographic apparatus 100 compared to silicon. Carbon and boron are less likely to deposit on reflecting surfaces within the lithographic apparatus 100 because they are readily etched away in the hydrogen plasma atmosphere within the lithographic apparatus 100. Outgassing of carbon and boron does not cause the same level of problems as outgassed silicon.

In an embodiment the cap layer 42 has a thickness of at most 10 nm. The thickness of the cap layer 42 is the dimension of the cap layer 42 measured in the direction perpendicular to the plane of the core layer 41. A smaller thickness for the cap layer 42 may be reduce the extent to which the cap layer 42 may be reduce the extent to which the cap layer 42 reduces the proportion of EUV radiation transmitted through the pellicle 80. In an embodiment the cap layer 42 has a thickness of at most 50 nm, optionally at most 20 nm, optionally at most 10 nm, optionally at most 5 nm and optionally at most 2 nm. A sufficiently thin cap layer 42 may remain in place during use of the pellicle 80 in the lithographic apparatus 100 without unduly reducing transmission of EUV radiation through the pellicle 80.

In an embodiment the core layer 41 comprises molybdenum. For example, the core layer 4 may comprise a compound 43 comprising molybdenum. The compound 43 may be MoSi₂ and/or MosSi₃. It is not essential for the compound to comprise molybdenum. In an embodiment the compound comprises SiₓC_{y} such as SiC. In an embodiment the compound 43 is embedded in a matrix 44 comprising silicon. The matrix 44 may comprises SiN and/or elemental Si. In an embodiment the compound 43 is formed as crystals. In an embodiment the core layer 41 consists of MoSi₂ and/or Mo₅Si₃ crystals embedded in a matrix 44 of SiN and/or Si.

As mentioned above, it is possible for the cap layer 42 to remain part of the pellicle 80 covering the core layer 41 during use of the lithographic apparatus 100. Alternatively, the cap layer 42 may be removed before the pellicle 80 is used in an exposure operation or during one or more exposure operations. The cap layer 42 may be a sacrificial layer to be removed to provide a bare core layer comprising silicon. After the cap layer 42 has been at least partially removed, the core layer 41 is exposed to the environment within the lithographic apparatus 100. Such a pellicle 80 without a cap layer 42 is depicted in FIG. 5. FIG. 5 shows the core layer 42 exposed to hydrogen plasma 45 in the lithographic apparatus 100.

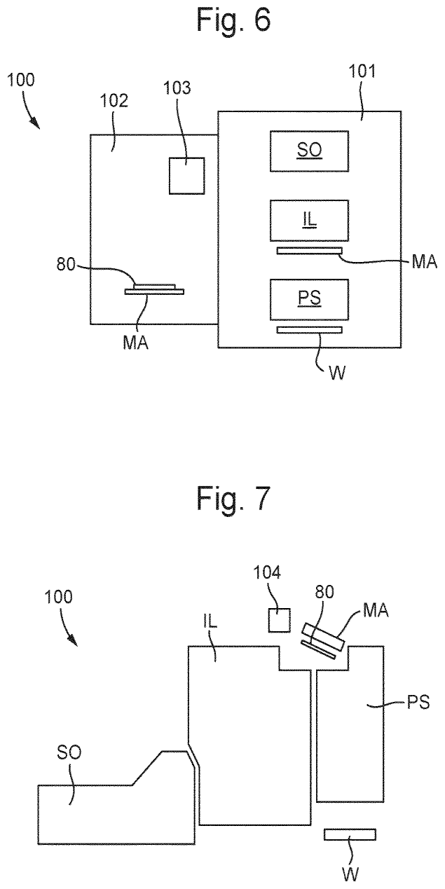

FIG. 6 schematically depicts a lithographic apparatus 100 according to an embodiment of the invention. As shown in FIG. 6, optionally the lithographic apparatus 100 comprises a low pressure environment 101 (which may also be referred to as a vacuum environment). The low pressure environment 101 may be substantially sealed off from the external atmosphere. The low pressure environment 101 may be connected to a low pressure source so as to maintain the vacuum within the low pressure environment 101.

As shown in FIG. 6, optionally the source collector module SO, the illumination system IL, the patterning device MA (supported by a support structure MT), the projection system PS and the substrate W (supported on the substrate table WT) may be located in the low pressure environment 101. A hydrogen plasma 45 may be present within the low pressure environment.

In an embodiment the pellicle 80 is located in the low pressure environment 101. The pellicle may comprise a core layer 41 comprising a compound 42 comprising molybdenum embedded in a matrix 44 comprising silicon. As shown in FIG. 5, in an embodiment the core layer 41 is exposed to the hydrogen plasma 45 in the low pressure environment 101. The rate of removal of silicon from the core layer 41 may be lower than the rate of removal of silicon from a native SiON layer. For example, bare silicon may etch of the order of ten times less rapidly than SiO and SiN compounds. An embodiment of the invention is expected to reduce the rate of removal of silicon from the pellicle 80.

A native SiON layer is less likely to form at a surface of the core layer 41 when the pellicle 80 is within the low pressure environment 101 compared to when the pellicle 80 is exposed to ambient atmosphere. The low pressure environment 101 may comprise a hydrogen plasma 45. The hydrogen plasma 45 forms a reducing atmosphere, thereby reducing the possibility of an oxide forming at the surface of the core layer 41. The core layer 41 exposed to the hydrogen plasma 45 may remain stable and exposed within the low pressure environment 101.

The cap layer 42 is removed so as to expose the core layer 41 to the low pressure environment 101. In an embodiment the cap layer is at least partially, and optionally completely, removed before the pellicle 80 is introduced into a low pressure environment 101. As shown in FIG. 6, in an embodiment the lithographic apparatus 100 comprises a loading bay 102. The loading bay 102 may be referred to as a load lock. The loading bay 102 is for holding a pellicle 80 to be introduced into the low pressure environment 101. The pellicle 80 is located in the loading bay 102 before the pellicle 80 is moved to the low pressure environment 101. The loading bay 102 allows components to be inserted into the low pressure environment 101 without unduly increasing the pressure within the low pressure environment 101.

When the pellicle 80 is input into the loading bay 102, the pellicle 80 may be combined with a patterning device MA, for example. The pellicle 80 may be combined with another component for a dynamic gas lock, for example. The pellicle 80 may be introduced into the loading bay 102 from the external environment. The external environment may be at a higher pressure than the low pressure environment 101. For example, the external environment may be atmospheric pressure. When the pellicle 80 is in the loading bay 102, the loading bay may be sealed and the pressure within the loading bay 102 reduced towards the pressure in the low pressure environment 101. The loading bay 102 may then be brought into spatial communication with the low pressure environment 101, for example by opening a window between the loading bay 102 and the low pressure environment 101. The pellicle 80 is moved from the loading bay 102 into the low pressure environment 101.

In an embodiment the cap layer 42 is at least partially, and optionally fully, removed from the pellicle 80 when the pellicle 80 is in the loading bay 102. As shown in FIG. 6, in an embodiment the loading bay 102 comprises an etcher 103. The etcher 103 is considered to etch away the cap layer 42 of a pellicle 80 so as to expose the core layer 41. The cap layer 42 may be etched when the pressure in the loading bay 102 is reduced to a similar pressure to that in the low pressure environment 101. This may reduce the possibility of a native SiON layer forming on the surface of the core layer 41 that is exposed after the cap layer 42 has been etched away. Alternatively, the cap layer 42 may be removed before the pressure in the loading bay 102 is reduced or during the lowering of the pressure in the loading bay 102. In an embodiment the loading bay 102 contains a hydrogen plasma. The reducing atmosphere within the loading bay 102 may reduce the possibility of a native SiON layer forming on the core layer 41.

The cap layer 42 comprises carbon and/or boron. In our embodiment the cap layer 42 consists of carbon and/or boron. Carbon and boron may be etched readily in a hydrogen plasma. In an embodiment the etcher 103 comprises a plasma source configured to provide hydrogen plasma for etching the cap layer 42. In an embodiment the etcher 103 comprises an ionising radiation source. The ionising radiation source is configured to ionise hydrogen gas in the loading bay 102 so as to produce hydrogen plasma 45. In an embodiment the ionising radiation source is configured to output microwave radiation. Microwave radiation readily ionises hydrogen gas. The ionising radiation source may accelerate etching of the cap layer 42. In an embodiment the ionising radiation source is controlled so as to move the beam of ionising radiation. This can help to improve the uniformity of exposure of the pellicle 80 to the hydrogen plasma 45.

In an embodiment the etcher 103 comprises an exciting radiation source. The exciting radiation source is configured to output exciting radiation, i.e. radiation for exciting material of the cap layer 42. In an embodiment the exciting radiation source is configured to output EUV radiation and/or DUV radiation. The exciting radiation may excite the material of the cap layer 42 and cause the material of the cap layer 42 to outgas. The power of the exciting radiation source may be controlled so as to control the rate of etching of the cap layer 42. The exciting radiation has a short wavelength so as to excite the material.

As a further alternative for removing the cap layer 42 in the loading bay 102, one or more chemicals may be used. The patterning device MA is more robust with respect to ionising radiation and the exciting radiation.

It is not essential for the cap layer 42 to be fully removed before the pellicle 80 is introduced into the low pressure environment 101. In an embodiment at least some, and optionally or, of the cap layer 42 remains on the pellicle 80 when the pellicle 80 is introduced into the low pressure environment 101 for use in exposure operations. In an embodiment the cap layer 42 is partially or fully removed while the pellicle 80 is within the low pressure environment 101. For example, the cap layer 42 may be etched away during an exposure operation for exposing a first substrate W. The image quality for the first substrate W may be slightly adversely affected by the presence of the cap layer 42. Once the cap layer 42 has been removed for, the image quality may no longer be reduced for subsequent substrate W. It may be that the cap layer 42 gradually reduces in thickness for the first one or more substrates W that are exposed. The cap layer 42 may be readily etched away within the low pressure environment 101 because of the presence of hydrogen plasma 45, the EUV radiation and the resulting high temperatures.

It is not essential for the cap layer 42 to be partly or fully removed before entering the low pressure environment 101 or while in the low pressure environment 101. In an embodiment the cap layer 42 may remain part of the pellicle 80 covering the core layer 41 during use of the pellicle 80 within the low pressure environment 101. As mentioned above, a sufficiently thin cap layer 41 may not significantly reduce the proportion of the EUV radiation that is transmitted through the pellicle 80. The cap layer 42 may be a permanent cap layer on the core layer 41.

FIG. 7 is a schematic diagram of a lithographic apparatus 100. According to an embodiment of the invention. As shown in FIG. 7, in an embodiment the lithographic apparatus 100 comprises a pellicle heater 104. The pellicle heater 104 is configured to maintain the pellicle 80 at a temperate of at least 500° C., optionally at least 600° C. and 700° C. By maintain the pellicle 80 at a high temperature, etching of the carbon and/or boron of the cap layer 42 may be reduced. For high temperatures the etching rate of carbon and/or boron reduces to a rate at which the cap layer 42 may remain as part of the pellicle 80 throughout the lifetime of the patterning device MA.

In an embodiment the pellicle heater 104 comprises a heating radiation source. The heating radiation source is configured to output heating radiation for heating the low pressure environment 101. The heating radiation sources configure to pump in heat into the low pressure environment 101 so as to maintain the pellicle 80 at a high temperature. For example, in an embodiment the heating radiation source is configured to provide infrared radiation for heating the pellicle 80. As shown in FIG. 7, in an embodiment the pellicle heater 104 is located adjacent to the pellicle 80. Alternatively, the pellicle heater 104 may be located elsewhere in the low pressure environment 101.

Additionally or alternatively, the pellicle heater 80 may comprise an ohmic heater. The ohmic heater is configured to pass an electric current through the pellicle 80, for example through the membrane 40 of the pellicle 80. The current heats up or maintains the temperature of the pellicle 80.

Additionally or alternatively, in an embodiment the pellicle heater 104 comprises a thermionic heater. The thermionic heater is configured to provide charged particles. For example, in an embodiment the thermionic heater comprises one or more electron guns to heat the membrane 40 of the pellicle 80.

As mentioned above, in an embodiment the pellicle 80 is made to have a core layer and at least one cap layer 42 comprising carbon and/or boron. In an embodiment, the method for making the pellicle 80 comprises a step of depositing a core layer 41 comprising silicon. For example, the core layer 41 may be deposited by a sputtering method. The method may further comprise depositing a cap layer 42 at least one major surface of the core layer 41.

In an embodiment the core layer 41 is deposited in a vacuum. The cap layer 42 is subsequently deposited while maintaining the vacuum. By maintaining the vacuum, the possibility of a native SiON layer forming on a surface of the core layer 41 before the position of the cap layer 42 is reduced. In an embodiment the cap layer 42 is deposited on the core layer 41 immediately after deposition of the core layer 41.

Additionally or alternatively, any native SiON layer formed at a surface of the deposited core layer 41 may be etched away before depositing the cap layer 42. In an embodiment an etchant is used to etch away any native SiON layer before deposition of the cap layer 42. For example, the component may be exposed to an etchant such as HF before the carbon and/or boron cap layer 42 is deposited. This may help to minimise the growth of native oxide at a surface of the core layer 41.

The features of the various embodiments described in this document can be combined with each other, unless it is clear that features are technically incompatible with each other. For example, a sacrificial layer comprising at least one of carbon, boron and SiON may be partially removed in the loading bay and further removed in the exposure environment which may additionally be heated to reduce outgassing of silicon from the pellicle.

In an embodiment the method for making the pellicle 80 comprises depositing layers of a substrate. The substrate may form the bulk of the frame 81 in the finished pellicle 80. The substrate may be etched away so as to expose the membrane 40 of the pellicle 80 while leaving part of the substrate to form the frame 81. A mask may be used so as to selectively etch away the substrate.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

While specific embodiments of the invention have been described above, it will be appreciated that the invention may be practiced otherwise than as described. For example, the various photo resist layers may be replaced by non-photo resist layers that perform the same function.

The descriptions above are intended to be illustrative, not limiting. Thus it will be apparent to one skilled in the art that modifications may be made to the invention as described without departing from the scope of the claims set out below.

1. A pellicle for EUV lithography, the pellicle comprising:
a core layer comprising silicon and having at least one non-oxidised surface; and
a cap layer at at least one major surface of the core layer,
wherein the cap layer comprises carbon and/or boron.

2. The pellicle of claim 1, wherein the cap layer has a thickness of at most 10 nm.

3. The pellicle of claim 1, wherein the core layer comprises crystals of a compound embedded in a matrix.

4. The pellicle of claim 3, wherein the matrix comprises silicon.

5. The pellicle of claim 4, wherein the matrix comprises SiN and/or elemental Si.

6. The pellicle of any of claim 3, wherein the compound comprises molybdenum.

7. The pellicle of claim 6, wherein the compound comprises MoSi₂ and/or Mo₅Si₃.

8. The pellicle of claim 1, wherein the core comprises SiₓC_{y}.

9. The pellicle of claim 1, wherein the cap layer is a sacrificial layer to be removed so as to provide a bare core.

10. The pellicle of claim 1, wherein the cap layer comprises at least one selected from the group consisting of SiOₓ, SiN_{y} and SiOₓN_{y}.

11.-22. (canceled)

23. An EUV lithographic apparatus comprising:
a low pressure environment for an EUV radiation beam path for an exposure operation; and
a pellicle located in the low pressure environment, the pellicle comprising a core layer comprising silicon and a cap layer comprising carbon and/or boron at at least one major surface of the core layer; and
a pellicle heater configured to maintain the pellicle at a temperature of at least 500° C.

24. The EUV lithographic apparatus of claim 23, wherein the pellicle heater comprises a heating radiation source.

25. The EUV lithographic apparatus of claim 24, wherein the heating radiation source is configured to provide infrared radiation for heating the pellicle.

26. The EUV lithographic apparatus of claim 23, wherein the pellicle heater comprises an ohmic heater configured to pass an electric current through the pellicle.

27. The EUV lithographic apparatus of claim 23, wherein the pellicle heater comprises a thermionic heater configured to provide charged particles.

28. A method for making a pellicle for EUV lithography, the method comprising:
depositing a core layer comprising silicon and having at least one non-oxidised surface; and
depositing a cap layer at at least one major surface of the core layer, wherein the cap layer comprises carbon and/or boron.

29.-40. (canceled)

41. The EUV lithographic apparatus of claim 23, further comprising a loading bay to hold the pellicle to be introduced into the low pressure environment, wherein the loading bay comprises an etcher configured to etch away the cap layer of a pellicle so as to expose the core layer.

42. The EUV lithographic apparatus of claim 41, wherein the etcher comprises a plasma source configured to provide hydrogen plasma for etching the cap layer.

43. The EUV lithographic apparatus of claim 41, wherein the etcher comprises an ionising radiation source configured to ionise hydrogen gas in the loading bay so as to produce hydrogen plasma.

44. The EUV lithographic apparatus of claim 43, wherein the ionising radiation source is configured to provide microwave radiation for ionising hydrogen gas.
